(19) United States
(12) Patent Application Publication
(10) Pub. No.: US 2025/0286530 A1
(43) Pub. Date: Sep. 11, 2025

(54) BULK ACOUSTIC WAVE DEVICE WITH FRAME STRUCTURE OUTSIDE OF ACTIVE REGION

(71) Applicant: Skyworks Global Pte. Ltd., Singapore (SG)

(72) Inventors: Zongliang Cao, Irvine, CA (US); Yanbo He, Irvine, CA (US); Kwang Jae Shin, Yongin-si (KR)

(21) Appl. No.: 19/071,442

(22) Filed: Mar. 5, 2025

Related U.S. Application Data
(60) Provisional application No. 63/562,621, filed on Mar. 7, 2024.
(60) Provisional application No. 63/562,597, filed on Mar. 7, 2024.
(60) Provisional application No. 63/562,580, filed on Mar. 7, 2024.

(51) Int. Cl. H03H 9/05; H03H 9/02; H03H 9/17; H03H 9/54

(52) U.S. Cl. CPC H03H 9/0504; H03H 9/02015; H03H 9/02118; H03H 9/17; H03H 9/542

(57) ABSTRACT

Aspects of this disclosure relate to a bulk acoustic wave device having an active region and a frame region outside of the active region. The bulk acoustic wave device can include an acoustic reflector, electrodes including a first electrode and a second electrode, a piezoelectric layer, and a frame structure positioned over the acoustic reflector in the frame region and outside of the active region. The first electrode and the second electrode can be on opposing sides of the piezoelectric layer over the acoustic reflector in the active region. Related filters, multiplexers, radio frequency modules, radio frequency systems, wireless communication devices, and methods are disclosed.

### CROSS REFERENCE TO PRIORITY APPLICATIONS

Any and all applications for which a foreign or domestic priority claim is identified in the Application Data Sheet as filed with the present application are hereby incorporated by reference under 37 C.F.R. § 1.57. This application claims the benefit of priority of U.S. Provisional Application No. 63/562,580, filed Mar. 7, 2024 and titled “BULK ACOUSTIC WAVE DEVICE WITH FRAME STRUCTURE OUTSIDE OF ACTIVE REGION,” and claims the benefit of priority of U.S. Provisional Application No. 63/562,597, filed Mar. 7, 2024 and titled “BULK ACOUSTIC WAVE DEVICE WITH RAISED FRAME LAYERS POSITIONED ON OPPOSING SIDES OF PIEZOELECTRIC LAYER,” and claims the benefit of priority of U.S. Provisional Application No. 63/562,621, filed Mar. 7, 2024 and titled “BULK ACOUSTIC WAVE DEVICE WITH SYMMETRIC FRAME STRUCTURE,” the disclosures of each of which are hereby incorporated by reference in their entireties and for all purposes.

### BACKGROUND

### Technical Field

The disclosed technology relates to acoustic wave devices. Embodiments of this disclosure relate to bulk acoustic wave devices with a frame structure positioned in a frame region outside of an active region.

### Description of Related Technology

Acoustic wave filters can be implemented in radio frequency electronic systems. For instance, filters in a radio frequency front end of a mobile phone can include acoustic wave filters. An acoustic wave filter can be a band pass filter. A plurality of acoustic wave filters can be arranged as a multiplexer. For example, two acoustic wave filters can be arranged as a duplexer.

An acoustic wave filter can include a plurality of acoustic wave resonators arranged to filter a radio frequency signal. Example acoustic wave resonators include surface acoustic wave (SAW) resonators and bulk acoustic wave (BAW) resonators. In BAW resonators, acoustic waves propagate in the bulk of a piezoelectric layer. Example BAW resonators include film bulk acoustic wave resonators (FBARs) and BAW solidly mounted resonators (SMRs).

For BAW devices, achieving a high quality factor (Q) is generally desirable. Suppressing and/or attenuating spurious mode(s) in BAW devices is also generally desirable. There are technical challenges related to increasing Q and further suppressing spurious mode(s) while meeting other performance specifications for BAW devices.

### SUMMARY OF CERTAIN INVENTIVE ASPECTS

The innovations described in the claims each have several aspects, no single one of which is solely responsible for its desirable attributes. Without limiting the scope of the claims, some prominent features of this disclosure will now be briefly described.

One aspect of this disclosure is a bulk acoustic wave device having an active region and a frame region outside of the active region. The bulk acoustic wave device includes an acoustic reflector, electrodes including a first electrode and a second electrode, a piezoelectric layer, and a frame structure positioned over the acoustic reflector in the frame region and outside of the active region. The first electrode and the second electrode are on opposing sides of the piezoelectric layer over the acoustic reflector in the active region.

The frame structure can include a raised frame structure. The frame structure can include a multi-layer raised frame structure. The frame structure can include a recessed frame structure.

The frame structure can be positioned between the piezoelectric layer and one of the electrodes. The first electrode can be positioned between the frame structure and the piezoelectric layer.

The frame region can laterally surround the active region. The frame region can be spaced apart from the active region by an intermediate region.

The acoustic reflector can be an air cavity.

The frame structure can be symmetric about an axis extending through the piezoelectric layer. The frame structure can include a first raised frame layer and a second raised frame layer, in which the first raised frame layer is on an opposite side of the piezoelectric layer than the second raised frame layer.

A surface of the piezoelectric layer can be flat at least in the active region. The surface of the piezoelectric layer can be flat in an intermediate region between the active region and the frame region.

The frame structure can include a gap between the second electrode and the piezoelectric layer that creates a suspended frame structure.

The first electrode can be shorted to metal on an opposing side of the piezoelectric layer.

Another aspect of this disclosure is a bulk acoustic wave device that includes an acoustic reflector, electrodes including a first electrode and a second electrode, a piezoelectric layer positioned vertically between the first and second electrodes over the acoustic reflector in an active region, and a frame structure over the acoustic reflector in a frame region and outside the active region. The first and second electrodes overlap in the active region. The frame region is laterally offset from the active region.

The frame region can laterally surround the active region.

The acoustic reflector can be an air gap.

Another aspect of this disclosure is a bulk acoustic wave device having an active region and a frame region outside of the active region. The bulk acoustic wave device includes an acoustic reflector, electrodes including a first electrode and a second electrode, a piezoelectric layer having a first side and a second side opposite the first side, and a frame structure positioned in the frame region and outside the active region. The first electrode is positioned on the first side. The second electrode is positioned on the second side. The piezoelectric layer and the first electrode and the second electrode overlap over the acoustic reflector in the active region. The frame structure includes a first raised frame layer over the acoustic reflector and a second raised frame layer over the acoustic reflector. The first raised frame layer is positioned on the first side. The second raised frame layer is positioned on the second side.

The first raised frame layer can be positioned between the first electrode and the piezoelectric layer. The second raised frame layer can be positioned between the second electrode and the piezoelectric layer.

The first electrode can be positioned between the first raised frame layer and the piezoelectric layer. The second electrode can be positioned between the second raised frame layer and the piezoelectric layer.

The frame structure can include a recessed frame structure. The frame structure can include a floating raised frame structure.

The frame region can be spaced apart from the active region by an intermediate region.

The acoustic reflector can be an air cavity.

The bulk acoustic wave device can include a support substrate and a dielectric layer between the support substrate and the piezoelectric layer. The first electrode can be positioned between the support substrate and the piezoelectric layer. The dielectric layer can be positioned laterally relative to the first electrode. The piezoelectric layer can have a flat side facing the support substrate.

Another aspect of this disclosure is a bulk acoustic wave device having an active region and a frame region outside of the active region. The bulk acoustic wave device includes an acoustic reflector, electrodes including a first electrode and a second electrode, a piezoelectric layer having a first side and a second side opposite the first side, and a frame structure positioned over the acoustic reflector in the frame region and outside the active region. The first electrode is positioned on the first side and the second electrode positioned on the second side. The piezoelectric layer, the first electrode, and the second electrode overlap over the acoustic reflector in the active region. The frame structure includes a first raised frame layer positioned between the first side of the piezoelectric layer and the first electrode. The frame structure includes a second raised frame layer positioned between the second side of the piezoelectric layer and the second electrode.

The frame structure can include a recessed frame structure. The frame structure can include a floating raised frame structure.

The frame region can be spaced apart from the active region by an intermediate region.

The acoustic reflector can be an air cavity.

The bulk acoustic wave device can include a support substrate and a dielectric layer between the support substrate and the piezoelectric layer. The first electrode can be positioned between the support substrate and the piezoelectric layer. The dielectric layer can be positioned laterally relative to the first electrode. The piezoelectric layer can have a flat side facing the support substrate.

Another aspect of this disclosure is a bulk acoustic wave device having an active region and a frame region outside of the active region. The bulk acoustic wave device includes a first electrode, a second electrode, a piezoelectric layer, and a symmetric frame structure positioned in the frame region and outside the active region. The first electrode and the second electrode overlap and are on opposing sides of the piezoelectric layer in the active region.

The symmetric frame structure can be symmetric about an axis extending through the piezoelectric layer. The symmetric frame structure can be symmetric about the axis with a symmetry tolerance magnitude of within 500 nanometers.

The symmetric frame structure can be point symmetric about a point in the bulk acoustic wave device. The symmetric frame structure can be point symmetric about the point with a symmetry tolerance magnitude of within 500 nanometers.

The symmetric frame structure can include a raised frame structure positioned on a same side of the piezoelectric layer on opposite sides of the active region.

The symmetric frame structure can include a first raised frame layer and a second raised frame layer, in which the first raised frame layer and the second raised frame layer are on opposite sides of the piezoelectric layer.

The symmetric frame structure can include a floating raised frame structure.

The bulk acoustic wave device can include an air cavity, in which the active region is over the air cavity and the symmetric frame structure is positioned over the air cavity.

The bulk acoustic wave device can include a support substrate. The first electrode can be positioned between the support substrate and the piezoelectric layer. The first electrode can be connected to metal buried in the support substrate. The bulk acoustic wave device can include a dielectric layer between the support substrate and the piezoelectric layer.

Another aspect of this disclosure is a bulk acoustic wave device having an active region and a frame region outside of the active region. The bulk acoustic wave device includes a first electrode, a second electrode, a piezoelectric layer, a frame structure positioned in the frame region and outside the active region. The piezoelectric layer, the first electrode, and the second electrode overlap in the active region. The frame structure is symmetric about an axis extending through the piezoelectric layer.

The frame structure can be symmetric about the axis with a symmetry tolerance magnitude of within 500 nanometers.

The frame structure can be reflection symmetric about the axis. The axis can extend vertically along a thickness of the piezoelectric layer.

The frame structure can include a first raised frame layer and a second raised frame layer. The first raised frame layer can be positioned on a first side of the piezoelectric layer and the second raised frame layer can be positioned on a second side of the piezoelectric layer opposite the first side. The axis can extend diagonally through the piezoelectric layer such that first raised frame layer and the second raised frame layer are symmetric about the axis.

The frame structure can include a raised frame structure and a recessed frame structure. The frame structure can include a floating raised frame structure.

Another aspect of this disclosure is an acoustic wave filter for filtering a radio frequency signal. The acoustic wave filter includes a bulk acoustic wave device in accordance with any suitable principles and advantages disclosed herein and a plurality of additional acoustic wave resonators. The bulk acoustic wave device and the plurality of additional acoustic wave resonators are configured to filter the radio frequency signal.

Another aspect of this disclosure is a multiplexer for filtering radio frequency signals. The multiplexer includes a first filter including a bulk acoustic wave device in accordance with any suitable principles and advantages disclosed herein, and a second filter coupled to the first filter at a common node.

Another aspect of this disclosure is a radio frequency module that includes a filter including a bulk acoustic wave device in accordance with any suitable principles and advantages disclosed herein, radio frequency circuitry, and a package structure enclosing the filter and the radio frequency circuitry.

Another aspect of this disclosure is a radio frequency system that includes an antenna, a filter including a bulk acoustic wave device in accordance with any suitable principles and advantages disclosed herein, and an antenna switch configured to selectively electrically connect the antenna and a signal path that includes the filter.

Another aspect of this disclosure is a wireless communication device that includes a radio frequency front end including a filter that includes a bulk acoustic wave device in accordance with any suitable principles and advantages disclosed herein, an antenna coupled to the radio frequency front end, a transceiver in communication with the radio frequency front end, and a baseband system in communication with the transceiver.

Another aspect of this disclosure is a method of radio frequency signal processing. The method includes receiving a radio frequency signal via at least an antenna; and filtering the radio frequency signal with a filter that includes a bulk acoustic wave device in accordance with any suitable principles and advantages disclosed herein.

The present disclosure relates to U.S. patent application Ser. No.______ [Attorney Docket SKYWRKS.1550A2], titled “BULK ACOUSTIC WAVE DEVICE WITH RAISED FRAME LAYERS POSITIONED ON OPPOSING SIDES OF PIEZOELECTRIC LAYER,” filed on even date herewith, the entire disclosure of which is hereby incorporated by reference herein. The present disclosure relates to U.S. patent application Ser. No.______ [Attorney Docket SKYWRKS.1550A3], titled “BULK ACOUSTIC WAVE DEVICE WITH SYMMETRIC FRAME STRUCTURE,” filed on even date herewith, the entire disclosure of which is hereby incorporated by reference herein.

### BRIEF DESCRIPTION OF THE DRAWINGS

Embodiments of this disclosure will now be described, by way of non-limiting example, with reference to the accompanying drawings.

FIG. 1 is a schematic cross-sectional side view of a bulk acoustic wave (BAW) device according to an embodiment.

FIG. 2 is a schematic cross-sectional side view of a BAW device according to another embodiment.

FIG. 3 is a schematic cross-sectional side view of a BAW device according to another embodiment.

FIG. 4A is a schematic cross-sectional side view of a BAW device according to another embodiment.

FIG. 4B is a schematic cross-sectional side view of a BAW device according to another embodiment.

FIG. 4C is a schematic cross-sectional side view of a BAW device according to another embodiment.

FIG. 5A is a schematic cross-sectional side view of a BAW device

according to another embodiment.

FIG. 5B is a schematic cross-sectional side view of a BAW device according to another embodiment.

FIG. 6A is a schematic cross-sectional side view of a BAW device according to another embodiment.

FIG. 6B is a schematic cross-sectional side view of a BAW device

according to another embodiment.

FIG. 7A is a schematic cross-sectional side view of a BAW device according to another embodiment.

FIG. 7B is a schematic cross-sectional side view of a BAW device according to another embodiment.

FIG. 7C is a schematic cross-sectional side view of a BAW device according to another embodiment.

FIG. 8A is a schematic cross-sectional side view of a BAW device according to another embodiment.

FIG. 8B is a schematic cross-sectional side view of a BAW device according to another embodiment.

FIG. 9 is an example schematic top plan view of a BAW device.

FIG. 10 is an example of a BAW solidly mounted resonator (SMR) according to an embodiment.

FIG. 11 is a schematic cross-sectional side view of a BAW device according to another embodiment.

FIG. 12A is a schematic diagram of a ladder filter that includes one or more BAW resonators according to an embodiment.

FIG. 12B is schematic diagram of a band pass filter.

FIGS. 13A, 13B, 13C, and 13D are schematic diagrams of multiplexers that include a filter with one or more BAW resonators according to an embodiment.

FIGS. 14, 15, and 16 are schematic block diagrams of modules that include a filter with one or more BAW resonators according to an embodiment.

FIG. 17 is a schematic block diagram of a wireless communication device that includes a filter with one or more BAW resonators according to an embodiment.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings. Any suitable principles and advantages of the embodiments disclosed herein can be implemented together with each other. The headings provided herein are for convenience only and are not intended to affect the meaning or scope of the claims.

Increasing the quality factor (Q) of a given bulk acoustic wave (BAW) resonator can effectively reduce energy losses. Such energy losses can include, for example, insertion losses within a filter or phase noise in an oscillator. BAW resonator performance can be enhanced and/or optimized by one or more of area, geometry, frame structure, or the like. BAW devices can include frame structures, such as raised frame structures and/or recessed frame structures.

BAW devices can include frame structures. A frame structure is a structure that adjusts mass loading in a portion of a BAW device over an acoustic reflector. A frame structure can include a raised frame structure that adds mass loading and/or a recessed frame structure that reduces mass loading. A raised frame structure can include an additional layer and/or a thicker portion of material that increases mass loading in a portion of a BAW device relative to a main acoustically active region. In some applications, a raised frame layer can include a different material than layers in contact with the raised frame layer. In some applications, a raised frame layer can include a same material as a layer in contact with the raised frame layer. A raised frame structure can be a multi-layer structure that includes two or more raised frame layers. A recessed frame structure can include a thinner portion of a layer of a BAW device that decreases mass loading in a portion of the BAW device relative to a main acoustically active region. Certain BAW devices include a frame structure around the main acoustically active region of the BAW device. Such a frame structure can be included around a periphery of the BAW device. In certain applications, the frame structure can surround the main acoustically active region in plan view. In some other applications, the frame structure can be around some but not all of the main acoustically active region in plan view.

A BAW device can include a pair of electrodes (a first electrode and a second electrode) and a piezoelectric layer positioned between the first and second electrodes. A region in which the pair of electrodes and the piezoelectric layer overlap over an acoustic reflector can define an acoustically active region. A frame structure, such as a raised frame and/or a recessed frame, can be positioned at an edge portion within the acoustically active region to reduce lateral energy leakage from the acoustically active region. A region of the BAW device that includes the frame structure can be referred to as a frame region. A raised frame structure can create a resonance at a frequency that is below a resonant frequency of the main acoustically active region of the BAW device when the raised frame structure overlaps with the pair of electrodes and the piezoelectric layer over the acoustic reflector. This resonance can be below a main resonant frequency of the BAW device. A resonance associated with the raised frame structure can be referred to as a frame mode, and more specifically a raised frame mode. The raised frame mode can be undesirable in certain applications.

BAW devices disclosed herein can achieve desirable performance by including a frame structure in a frame region outside of the active region. The BAW devices according to various embodiments disclosed herein can reduce lateral energy leakage from the acoustically active region while suppressing or eliminating a raised frame mode. In some embodiments, the frame structure can include a first raised frame layer that is positioned on a first side of a piezoelectric layer and a second raised frame layer positioned on a second side of the piezoelectric layer. In some embodiments, the frame structure can be symmetric about an axis extending through the piezoelectric layer. A variety of BAW devices with a frame structure outside of an active region are described herein. Any suitable principles and advantages of these BAW devices can be implemented together with each other.

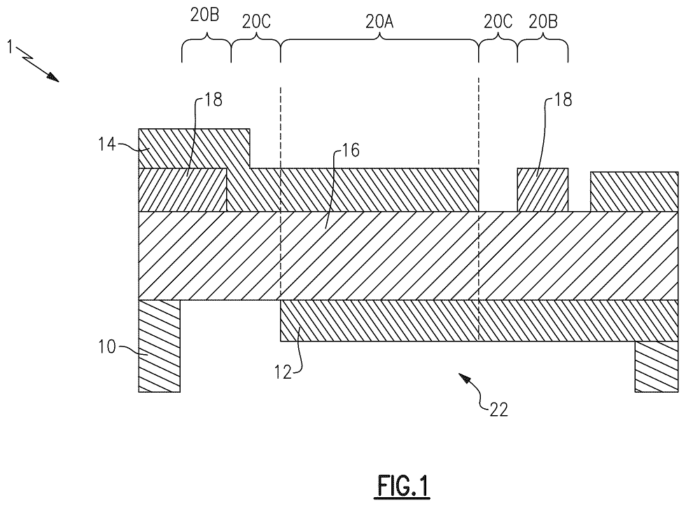

FIG. 1 is a schematic cross-sectional side view of a bulk acoustic wave (BAW) device 1 according to an embodiment. The BAW device 1 can include a support substrate 10, a pair of electrodes (e.g., a first electrode 12 and a second electrode 14), a piezoelectric layer 16 positioned between the first and second electrodes 12 and 14, respectively, a frame structure 18, and an air cavity 22. The BAW device 1 can have an active region 20A, a frame region 20B outside of the active region 20A, and an intermediate region 20C between the active region 20A and the frame region 20B. The frame region 20B can surround the active region 20A in plan view. The piezoelectric layer 16, the first electrode 12, and the second electrode 14 overlap over the air cavity 22 in the active region 20A. The frame structure 18 is positioned over the air cavity 22 in the frame region 20B and outside of the active region 20A. As illustrated, the frame region 20B is the region that includes the frame structure 18 over the air cavity 22.

The frame structure 18 can include a raised frame structure, which can be configured to suppress the transverse mode. The raised frame structure can reduce or impede propagation of transverse mode. The frame structure 18 can include a material that has a relatively high mass density. For instance, the frame structure 18 can include molybdenum (Mo), tungsten (W), ruthenium (Ru), the like, or any suitable alloy thereof. The frame structure 18 can be a metal layer. Alternatively, the frame structure 18 can be a suitable non-metal material with a relatively high density. The density of the frame structure 18 can be similar to or heavier than the density of the first electrode 12 or the second electrode 14. The frame structure 18 can include a low acoustic impedance material that has a lower acoustic impedance than the first electrode 12, the second electrode 14, and/or the piezoelectric layer 16. For example, the frame structure 18 can include a silicon dioxide (SiO₂) layer, a silicon nitride (SiN) layer, a silicon carbide (SiC) layer, or any other suitable low acoustic impedance layer. The frame structure 18 can be a dielectric layer. The frame structure 18 can be an oxide layer.

The frame structure 18 can include, for example, a single layer raised frame structure, a multi-layer raised frame structure, or a combination of a raised frame structure and a recessed frame structure. As an example, the frame structure 18 can have a multi-layer raised frame structure that includes a relatively high density layer and a relatively low acoustic impedance layer. The low acoustic impedance layer can contribute to reducing an effective electromechanical coupling coefficient (k²) relative to a single high-density raised frame structure, which can reduce excitation strength of a raised frame spurious mode. As another example, a floating raised frame structure can be implemented.

The frame structure 18 is positioned in the frame region 20B that is outside of the active region 20A. In the illustrated embodiment, the frame region 20B can be spaced apart from the active region 20A by the intermediate region 20C. However, in some embodiments, the frame structure 18 can be positioned in the frame region 20B and abut the active region 20A without the intermediate region 20C.

The support substrate 10 can be a semiconductor substrate. The support substrate 10 can be a silicon substrate. The support substrate 10 can be any other suitable support substrate, such as a substrate of quartz, silicon carbide, sapphire, glass, gallium arsenide, or any suitable ceramic (e.g., spinel, alumina, etc.). The support substrate 10 can be part of a support structure that includes, for example, the support substrate 10, a trap rich layer (not shown), a passivation layer (not shown), or one or more intermediate layers therebetween (not shown).

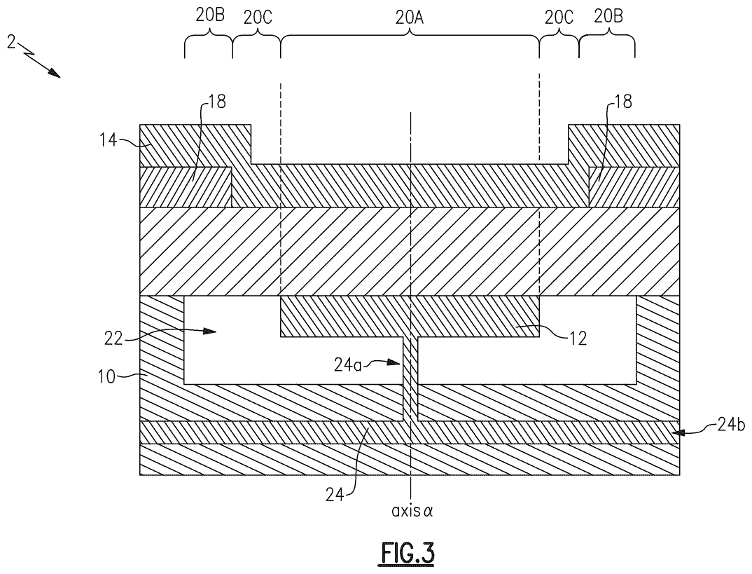

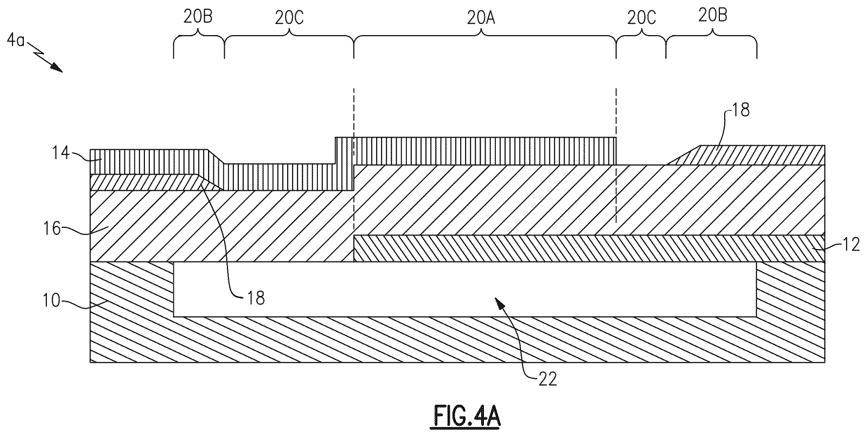

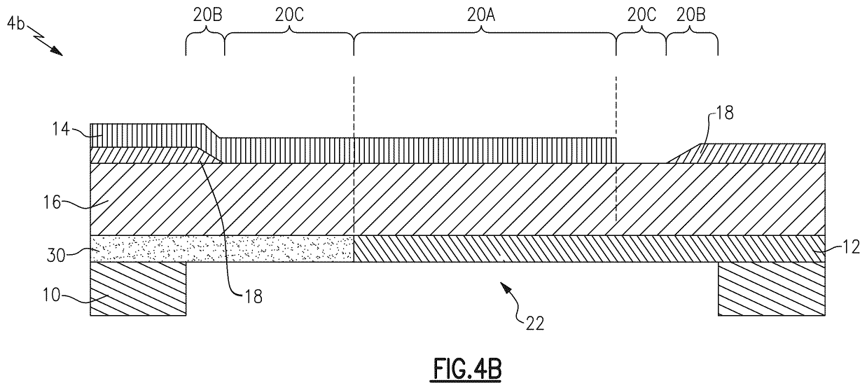

The air cavity 22 can be formed between the substrate 10 and the first electrode 12. While not shown in FIG. 1, the substrate 10 extends under the air cavity 22 opposite the first electrode 12. A substrate extending under an air cavity is shown, for example, in FIGS. 3, 4A, and 4C. Any of the BAW devices disclosed herein that include an air cavity can have a substrate extending under the air cavity. The air cavity 22 is an example of an acoustic reflector. The BAW device 1 can be a film bulk acoustic wave resonator (FBAR). In some other embodiments, there can be a solid acoustic mirror in place of the air cavity 22 and such a BAW device can be a BAW solidly mounted resonator (SMR).

The first electrode 12 can be referred to as a lower electrode. The first electrode 12 can have a relatively high acoustic impedance. The first electrode 12 can include molybdenum (Mo), tungsten (W), ruthenium (Ru), chromium (Cr), iridium (Ir), platinum (Pt), or any suitable alloy and/or combination thereof. Similarly, the second electrode 14 can have a relatively high acoustic impedance. The second electrode 14 can include Mo, W, Ru, Cr, Ir, Pt, or any suitable alloy and/or combination thereof. The second electrode 14 can be formed of the same material as the first electrode 12 in certain applications. The second electrode 14 can be referred to as an upper electrode. The thickness of the first electrode 12 can be approximately the same as the thickness of the second electrode 14 in the acoustically active region 20A of the BAW device 1.

The piezoelectric layer 16 can include a suitable material such as, but not limited to, aluminum nitride (AlN), zinc oxide (ZnO), or lead zirconium titanate (PZT). In certain applications, the piezoelectric layer 16 can be an AlN layer. The piezoelectric material can be doped or undoped. For example, an AlN-based piezoelectric layer can be doped with any suitable dopant, such as scandium (Sc), chromium (Cr), magnesium (Mg), sulfur(S), yttrium (Y), silicon (Si), germanium (Ge), oxygen (O), hafnium (Hf), zirconium (Zr), titanium (Ti), or the like. In certain applications, the piezoelectric layer 16 can be AlN based layer doped with Sc. Doping the piezoelectric layer 16 can adjust the resonant frequency. Doping the piezoelectric layer 16 can increase the electromechanical coupling coefficient (kt²) of the BAW device 1. Doping to increase the kt² can be advantageous at higher frequencies where kt² can be degraded.

In certain applications, two or more piezoelectric layers can be implemented with any suitable principles and advantages disclosed herein. The stacked piezoelectric layers can have c-axes oriented in opposite directions in the acoustically active region and excite an overtone mode as a main mode of a BAW resonator.

In certain applications, a frame structure is implemented in an edge portion of an active region where a pair of electrodes overlap on opposing sides of a piezoelectric layer over an acoustic reflector to suppress the transverse mode. Implementing the frame structure 18 in the frame region 20B that is outside of the active region 20A can increase the size (e.g., a lateral dimension) of the BAW device 1 as compared to a similar BAW device that implements a frame structure in the edge portion of the active region. Because of the size increase, frame structures have been included in the active region, especially when the size can be a crucial factor in designing a BAW device. However, when the frame structure is in the active region, a raised frame mode can be created in the BAW device. The frame structure 18 positioned in the frame region 20B that is outside of the active region 20A can enable the BAW device 1 to reduce lateral energy leakage from the active region 20A while also suppressing or eliminating the raised frame mode.

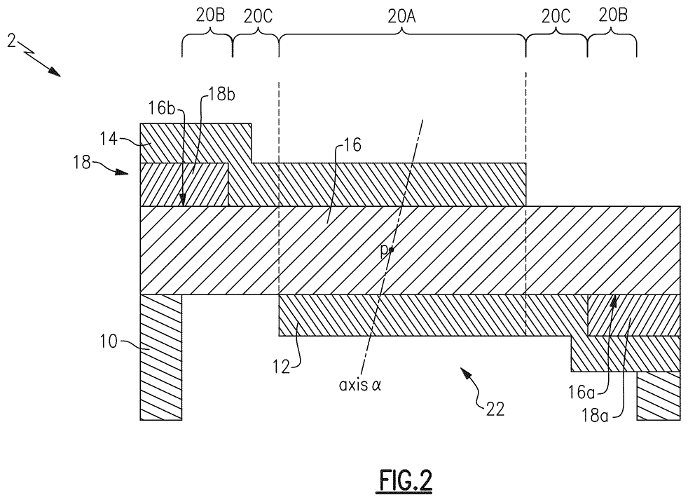

A frame structure 18 can be located over an acoustic reflector (e.g., the air cavity 22) in any suitable position outside of the active region 20A. For example, a BAW device can include a frame 18 structure partially or fully between the first electrode 12 and the piezoelectric layer 16, partially or fully between the second electrode 14 and the piezoelectric layer 16, embedded in the piezoelectric layer 16, or between the first electrode 12 and the piezoelectric layer 16 and between the second electrode 14 and the piezoelectric layer 16. Also, in some embodiments, the frame structure 18 can be structurally and/or functionally symmetric (e.g., reflection symmetry, rotational symmetry, translational symmetry, glide symmetry, point symmetry, or bilateral symmetry) (see, for example, FIGS. 2 and 3).

FIG. 2 is a schematic cross-sectional side view of a BAW device 2 according to an embodiment. Unless otherwise noted, the components of the BAW device 2 shown in FIG. 2 may be structurally and/or functionally the same as or generally similar to like components of other BAW devices disclosed herein. As with the BAW device 1, the BAW device 2 can include a support substrate 10, a pair of electrodes (e.g., a first electrode 12 and a second electrode 14), a piezoelectric layer 16 positioned between the first and second electrodes 12 and 14, respectively, in an active region 20A, and a frame structure 18 positioned in a frame region 20B that is outside of the active region 20A.

In the BAW device 2, the frame structure 18 can include a first raised frame layer 18a positioned on (e.g., on or directly on) a first side 16a of the piezoelectric layer 16 and a second raised frame layer 18b positioned on (e.g., on or directly on) a second side 16b of the piezoelectric layer 16. For example, the first raised frame layer 18a can be positioned between the first side 16a of the piezoelectric layer 16 and the first electrode 12, and the second raised frame layer 18b can be positioned between the second side 16b of the piezoelectric layer 16 and the second electrode 14.

The frame structure 18 (e.g., the first and second raised frame layers 18a, 18b) can be symmetric about an axis a extending through the piezoelectric layer 16. The frame structure 18 (e.g., the first and second raised frame layers 18a, 18b) can be symmetric about a point p. The axis a can be an arbitrary axis and illustrated as an example. In some embodiments, the first and second raised frame layers 18a, 18b can have identical structures and be designed to be symmetric about the axis a extending through the piezoelectric layer 16. There may be manufacturing tolerance(s) and the first and second raised frame layers 18a, 18b may not be completely symmetric. For example, the first and second raised frame layers 18a, 18b can be symmetric about the axis a with a symmetry tolerance magnitude of within 500 nanometers (nm), within 250 nm, within 200 nm, or within 100 nm. The symmetry tolerance can be dependent on resonant frequency of the BAW device 2, where higher frequencies can have smaller tolerances. The first and second raised frame layers 18a, 18b positioned symmetrically within the symmetry tolerance magnitude of within 500 nm, within 250 nm, within 200 nm, or within 100 nm can be considered being symmetric to one another. In some embodiments, the frame structure 18 can be considered symmetric about the axis a when the first raised frame layer 18a and the second raised frame layer 18b provides the same or substantially the same mass loading in the underlying portions of the piezoelectric layer 16. For example, the first and second raised frame layers 18a, 18b may have different shapes, dimensions, or materials but be considered symmetric about the axis a as long as the first and second raised frame layers 18a, 18b provide the same or substantially the same mass loading in the underlying portions of the piezoelectric layer 16.

When the frame structure 18 (e.g., the first and second raised frame layers 18a, 18b) is symmetric, a portion of the first raised frame layer 18a that overlaps the acoustic reflector (e.g., the air cavity 22) and a portion of the second raised frame layer 18b that overlaps the acoustic reflector (e.g., the air cavity 22) can have the same or generally similar widths. For example, the widths of the portions of the first and second raised frame layers 18a, 18b that overlap the acoustic reflector can have a difference of less than 500 nm, less than 250 nm, less than 200 nm, or less than 100 nm. The width of raised frame layers 18a, 18b over the acoustic reflector can have a tolerance that is dependent on resonant frequency of the BAW device 2, where higher frequencies have smaller tolerances. For instance, a raised frame width tolerance of within 500 nm can be suitable for a 2 gigahertz (GHz) resonant frequency and a tolerance within 200 nm can be suitable for a 5 GHz resonant frequency in certain applications. Also, a spacing (e.g., the intermediate region 20C) between the first electrode 12 and the second raised frame layer 18b and a spacing (e.g., the intermediate region 20C) between the second electrode 14 and the first raised frame layer 18a can be the same or substantially the same in the symmetric frame structure 18.

In some embodiments, the frame structure 18 (e.g., the first and second raised frame layers 18a, 18b) as well as the first and second electrodes 12, 14 can be symmetric about the axis a extending through the piezoelectric layer 16 and/or about the point p. For example, a combination of the first raised frame layer 18a and the first electrode 12 can be symmetric with a combination of the second raised frame layer 18b and the second electrode 14 such that the respective underlying portions of the piezoelectric layer 16 have the same or substantially the same resonant frequencies.

FIG. 3 is a schematic cross-sectional side view of a BAW device 3 according to an embodiment. Unless otherwise noted, the components of the BAW device 3 shown in FIG. 3 may be structurally and/or functionally the same as or generally similar to like components of other BAW devices disclosed herein. As with the BAW devices 1 and 2, the BAW device 3 can include a support substrate 10, a pair of electrodes (e.g., a first electrode 12 and a second electrode 14), a piezoelectric layer 16 positioned between the first and second electrodes 12 and 14 in an active region 20A, and a frame structure 18 positioned in a frame region 20B that is outside of the active region 20A.

In the BAW device 3, the frame structure 18 is designed to be symmetric about an axis a extending through the piezoelectric layer 16. A combination of the frame structure 18, the first electrode 12, and the second electrode 14 can be symmetric about the axis a. The frame structure 18 of the BAW device 3 is positioned between the second electrode 14 and the piezoelectric layer 16. The frame region 20B can laterally surround the active region 20A. The second electrode 14 can extend away from the active region 20A to at least the frame region 20B to provide symmetry about the axis a. To maintain the frame region 20B outside of the active region 20A, the first electrode 12 can terminate in the active region 20A. The electrical connection to and/or from the first electrode 12 can be made through a connection structure 24. The connection structure 24 can include a first portion 24a that extends from the first electrode 12 to the substrate 10 and a second portion 24b that extends at least partially through the substrate 10. The second portion 24b can be buried in the substrate 10 and at least partially extend laterally. The connection structure 24 can beneficially enable the combination of the frame structure 18, the first electrode 12, and the second electrode 14 to be symmetrical about the axis a while maintaining the frame structure 18 to be in the frame region 20B that is outside of the active region 20A.

FIG. 4A is a schematic cross-sectional side view of a BAW device 4a according to an embodiment. Unless otherwise noted, the components of the BAW device 4a shown in FIG. 4A may be structurally and/or functionally the same as or generally similar to like components of other BAW devices disclosed herein. The BAW device 4a can be generally similar to the BAW device 1 of FIG. 1. Unlike the BAW device 1, the piezoelectric layer 16 in the BAW device 4a has a shape (e.g., a stepped shape) that conforms with the shape of the first electrode 12. The BAW device 4a with the stepped shape piezoelectric layer 16 may be manufactured with a relatively simple manufacturing process. In some applications, a non-stepped or flat bottom piezoelectric layer may be more preferred to reduce the chances of cracking in the piezoelectric layer 16. FIG. 4B illustrates a BAW device 4b that is like the BAW device 4a except with a flat bottom piezoelectric layer 16.

Also, FIG. 4A illustrates that the frame structure 18 (e.g., a raised frame) can have a tapered edge. The tapered edge of the frame structure 18 may have a taper angle that is less than 90° or less than 45°. In the BAW device 4a, the frame structure 18 is on an opposite side of the piezoelectric layer 16 than the support substrate 10. The frame structure 18 of the BAW device 4a can be considered on a top size of the piezoelectric layer 16.

FIG. 4B is a schematic cross-sectional side view of a BAW device 4b according to an embodiment. Unless otherwise noted, the components of the BAW device 4b shown in FIG. 4B may be structurally and/or functionally the same as or generally similar to like components of other BAW devices disclosed herein. The BAW device 4b can be generally similar to the BAW devices 1 and 4a of FIGS. 1 and 4A, respectively. The BAW device 4b can include a dielectric layer 30 positioned between the support substrate 10 and the piezoelectric layer 16. The dielectric layer 30 can be referred to as a dielectric filler layer.

The dielectric layer 30 can have a thickness that is the same as or similar to a thickness of the first electrode 12. A surface of the dielectric layer 30 and a surface of the first electrode 12 can be flush with one another such that the piezoelectric layer 16 positioned over the surfaces of the dielectric layer 30 and the first electrode 12 has a flat surface facing the dielectric layer 30 and the first electrode 12. As compared to the stepped shape piezoelectric layer 16 of FIG. 4A, the generally flat piezoelectric layer 16 can be more reliable as the generally flat piezoelectric layer 16 can mitigate or prevent the piezoelectric layer 16 from cracking. The generally flat piezoelectric layer 16 can also contribute to enabling a more accurate modeling of the BAW device 4b, and to providing a relatively accurate simulation-measurement match. The generally flat piezoelectric layer 16 may contribute to reducing or avoiding unintentional acoustic wave scattering, which can reduce the propagation loss and provide improved quality factor (Q). In addition, when a material that has a relatively high thermal conductivity is used as the dielectric layer 30, improved heat dissipation can be obtained. For example, the dielectric layer 30 can have a thermal conductivity that is higher than a thermal conductivity of the piezoelectric layer 16.

FIG. 4C is a schematic cross-sectional side view of a BAW device 4c according to an embodiment. Unless otherwise noted, the components of the BAW device 4c shown in FIG. 4C may be structurally and/or functionally the same as or generally similar to like components of other BAW devices disclosed herein. The BAW device 4c can be generally similar to the BAW devices 1 and 4a of FIGS. 1 and 4A, respectively. The frame region 20B of the BAW device 4c can include a raised frame region RaF and a recessed frame region ReF. The frame structure 18 can define a raised frame structure in the raised frame region RaF. A thickness of the piezoelectric layer 16 can be thinner in the recessed frame region ReF than in the active region 20A and/or the raised frame region RaF. A recessed frame can alternatively or additionally be formed by (a) reducing the thickness of at least one of the first and second electrodes 12, 14 in the recessed frame region ReF and/or (b) reducing the thickness of a passivation layer in the recessed frame region ReF.

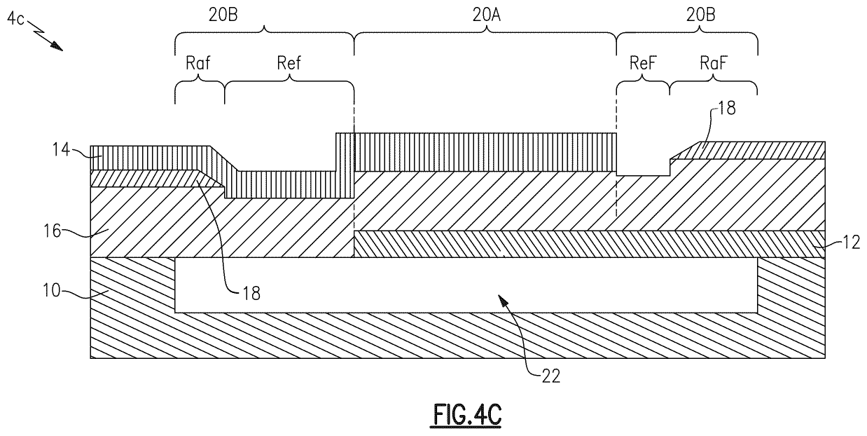

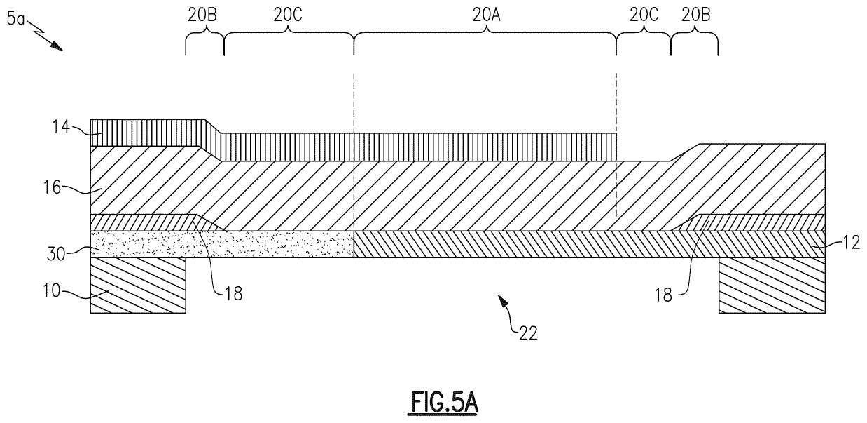

FIG. 5A is a schematic cross-sectional side view of a BAW device 5a according to an embodiment. Unless otherwise noted, the components of the BAW device 5a shown in FIG. 5A may be structurally and/or functionally the same as or generally similar to like components of other BAW devices disclosed herein. As with the BAW device 4b of FIG. 4B, the BAW device 5a can include a support substrate 10, a first electrode 12, a second electrode 14, a piezoelectric layer 16, a frame structure 18 in a frame region 20B outside of an active region 20A, and a dielectric layer 30. The frame structure 18 in the BAW device 5a is positioned between the support substrate 10 and the piezoelectric layer 16. For example, the frame structure 18 can be partially positioned between the first electrode 12 and the piezoelectric layer 16 and partially positioned between the dielectric layer 30 and the piezoelectric layer 16. In the BAW device 5a, the piezoelectric layer 16 has a flat bottom surface that is planar in the active region 20A and the intermediate region 20C.

FIG. 5B is a schematic cross-sectional side view of a BAW device 5b according to an embodiment. Unless otherwise noted, the components of the BAW device 5b shown in FIG. 5B may be structurally and/or functionally the same as or generally similar to like components of other BAW devices disclosed herein. The BAW device 5b can be generally similar to the BAW device 5a of FIG. 5A. However, the BAW device 5b does not include the dielectric layer 30. The piezoelectric layer 16 of FIG. 5B does not include a step at or near the edge of the active region 20A and the piezoelectric layer 16 has a generally flat surface at or near the edge of the active region 20A.

A method of manufacturing the BAW device 5b can include providing the support substrate 10 with a sacrificial layer (not shown) formed thereon, providing (e.g., depositing) the first electrode 12 over the support substrate 10 and/or the sacrificial layer, forming the frame structure 18 over the support substrate 10 and/or the sacrificial layer, providing the piezoelectric layer 16 over the support substrate 10, the sacrificial layer, the first electrode 12, and/or the frame structure 18, and providing the second electrode 14 over the piezoelectric layer 16. The method can also include removing the sacrificial layer. The portion of the BAW device 5b where the sacrificial layer was present can define the air cavity 22. When the piezoelectric layer 16 is formed, a surface of the sacrificial layer (prior to removal) and a surface of the first electrode 12 can be flush with one another such that the piezoelectric layer 16 positioned over the surfaces of the dielectric layer 30 and the first electrode 12 have a flat bottom surface.

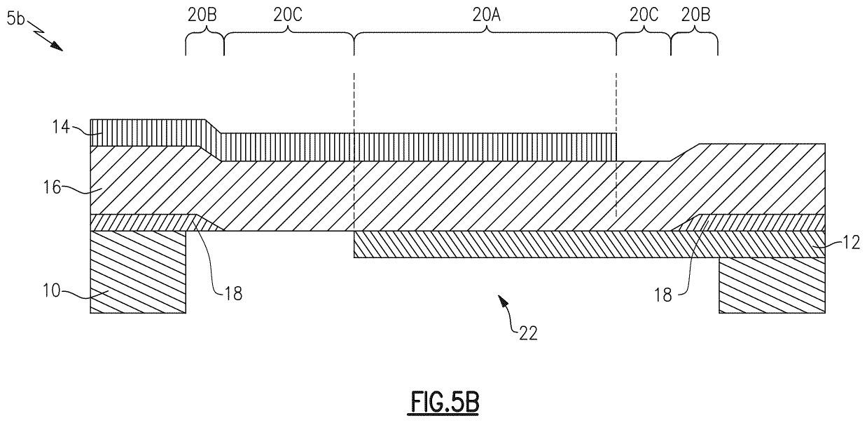

FIG. 6A is a schematic cross-sectional side view of a BAW device 6a according to an embodiment. Unless otherwise noted, the components of the BAW device 6a shown in FIG. 6A may be structurally and/or functionally the same as or generally similar to like components of other BAW devices disclosed herein. The BAW device 6a can include a support substrate 10, a pair of electrodes (e.g., a first electrode 12 and a second electrode 14), a piezoelectric layer 16 positioned between the first and second electrodes 12 and 14 in an active region 20A, a frame structure 18 positioned in a frame region 20B that is outside of the active region 20A, and a dielectric layer 30.

In the BAW device 6a, the second electrode 14 can be shorted to metal on an opposite side of the piezoelectric layer 16. The first electrode 12 can be part of a layer 40. The layer 40 can also include a shorted portion 42. The first electrode 12 and the shorted portion 42 can have the same material and be formed in the same process step. The first electrode 12 and the shorted portion 42 can be spaced apart and electrically isolated by the dielectric layer 30. The second electrode 14 can have a resonator portion 14a that is positioned on the opposing side of the piezoelectric layer 16 from the first electrode 12 and a shorted portion 14b that shorts the second electrode 14 and the shorted portion 42 of the layer 40. Shorting the second electrode 14 and the shorted portion 42 of the layer 40 can provide improved thermal dissipation ability and/or reduced ohmic loss in the second electrode 14 and/or the layer 40.

FIG. 6B is a schematic cross-sectional side view of a BAW device 6b according to an embodiment. Unless otherwise noted, the components of the BAW device 6b shown in FIG. 6B may be structurally and/or functionally the same as or generally similar to like components of other BAW devices disclosed herein. The BAW device 6b of FIG. 6B illustrates that the dielectric layer 30 may be omitted from the BAW device 6a. For example, the method described with respect to FIG. 5B may be utilized to form the separation between the first electrode 12 and the shorted portion 42 in the BAW device 6b.

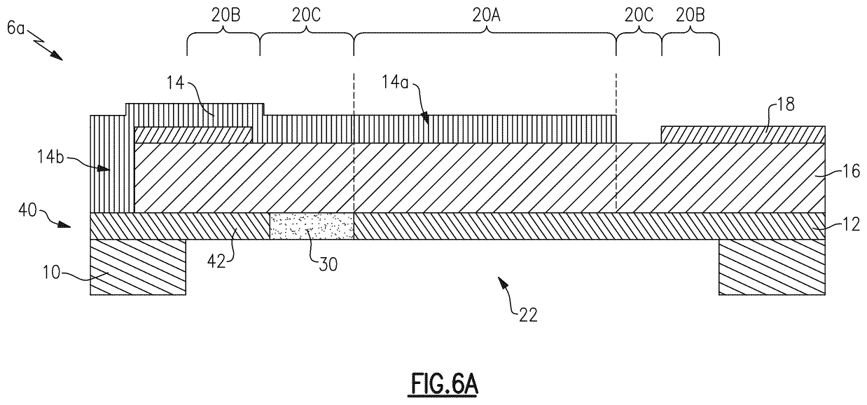

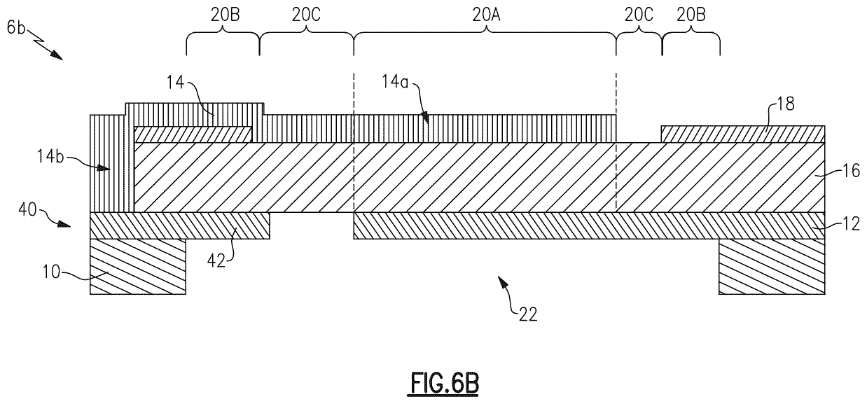

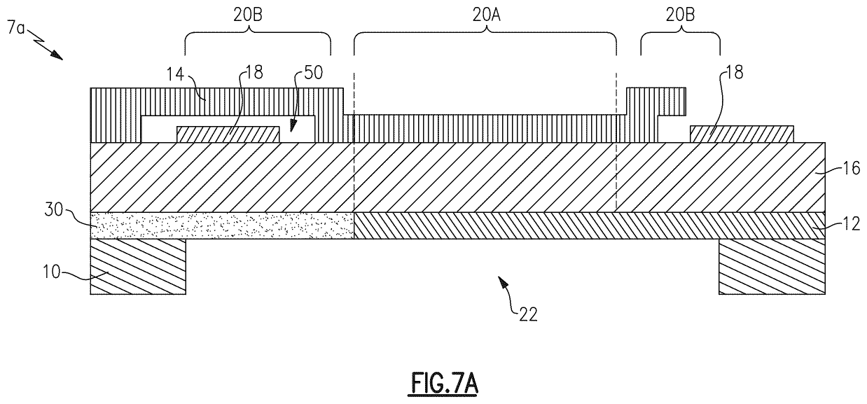

FIG. 7A is a schematic cross-sectional side view of a BAW device 7a according to an embodiment. Unless otherwise noted, the components of the BAW device 7a shown in FIG. 7A may be structurally and/or functionally the same as or generally similar to like components of other BAW devices disclosed herein.

A perimeter of the frame structure 18 of the BAW device 7a and the second electrode 14 can be spaced apart by a gap 50. The gap 50 can be filled with air and/or an electrically insulating material. The frame structure 18 can be electrically isolated from an electrode (e.g., the second electrode 14) of the BAW device 7a that is on the same side of the piezoelectric layer 16. The frame structure 18 of the BAW device 7a can be referred to as a floating raised frame structure. A floating raised frame structure can be at a floating voltage. The floating raised frame structure can contribute to improving the quality factor and Gamma loss in certain applications. The gap 50 can create a suspended frame structure, which can contribute to improving the energy confinement.

FIG. 7B is a schematic cross-sectional side view of a BAW device 7b according to an embodiment. Unless otherwise noted, the components of the BAW device 7b shown in FIG. 7B may be structurally and/or functionally the same as or generally similar to like components of other BAW devices disclosed herein. FIG. 7B illustrates that the floating raised frame and/or the suspended frame structure of the BAW device 7a shown in FIG. 7A can be combined with the various features of the BAW device 6b shown in FIG. 6B. As illustrated in FIG. 7B, the suspended frame structure can be shorted to metal on an opposite side of the piezoelectric layer 16.

FIG. 7C is a schematic cross-sectional side view of a BAW device 7c according to an embodiment. Unless otherwise noted, the components of the BAW device 7c shown in FIG. 7C may be structurally and/or functionally the same as or generally similar to like components of other BAW devices disclosed herein. The BAW device 7c can be generally similar to the BAW device 7a of FIG. 7A. Unlike the BAW device 7a, the suspended frame structure can omit the frame structure 18 and the gap 50 between the second electrode 14 and the piezoelectric layer 16 can create the suspended frame structure, in some embodiments.

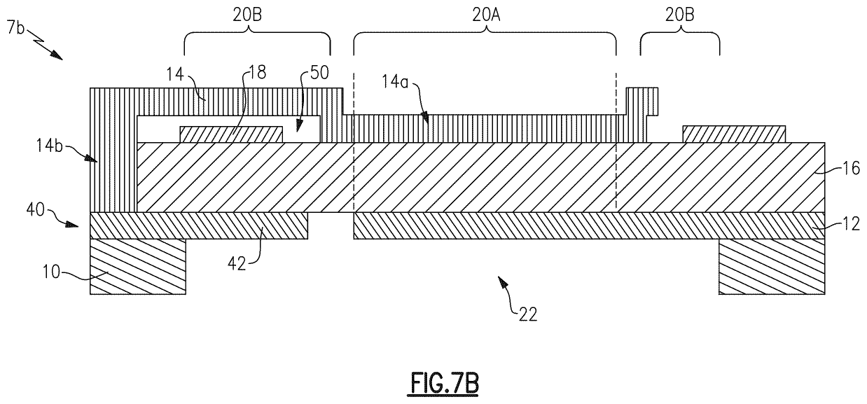

FIG. 8A is a schematic cross-sectional side view of a BAW device 8a according to an embodiment. Unless otherwise noted, the components of the BAW device 8a shown in FIG. 8A may be structurally and/or functionally the same as or generally similar to like components of other BAW devices disclosed herein. The BAW device 8a is generally similar to the BAW device 2 of FIG. 2, except that the first electrode 12 in the BAW device 8a is illustrated to have a flat shape and the piezoelectric layer 16 is conformally disposed over the first electrode 12 and the first raised frame layer 18a that is positioned on the first electrode 12. In the BAW device 8a, raised frame layers 18a and 18b are on opposite sides of the piezoelectric layer 16.

FIG. 8B is a schematic cross-sectional side view of a BAW device 8b according to an embodiment. Unless otherwise noted, the components of the BAW device 8b shown in FIG. 8B may be structurally and/or functionally the same as or generally similar to like components of other BAW devices disclosed herein. The BAW device 8b is generally similar to the BAW devices 2 of FIG. 2 and the BAW device 8a of FIG. 8A. However, in the BAW device 8b, the first raised frame layer 18a is positioned between the support substrate 10 and the first electrode 12, and the second electrode 14 is positioned between the piezoelectric layer 16 and the second raised frame layer 18b.

Any suitable combination of the features from two or more of FIGS. 1-8B can be implemented in a BAW device. In some embodiments, a BAW device can include one or more frame structures in a frame region that is outside of an active region, and the one or frame structures can be symmetric about an axis that extends through a piezoelectric layer of the BAW device. The one or more frame structures may include a first raised frame layer and a second raised frame layer that is positioned on opposing sides of the piezoelectric layer. The BAW device can be a FBAR or a BAW SMR.

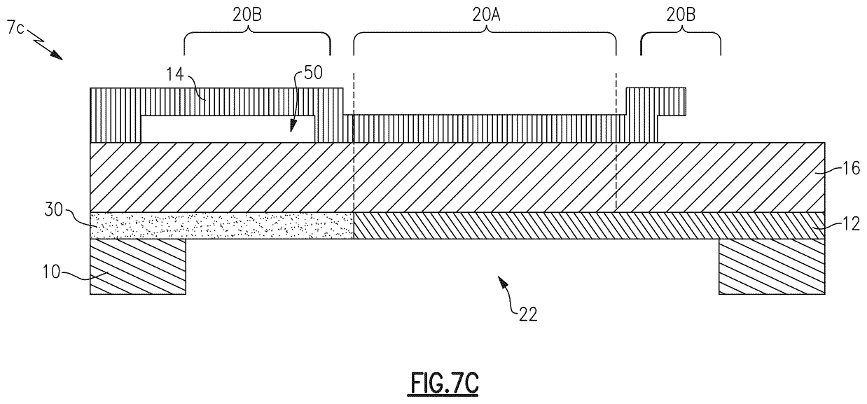

FIG. 9 is an example schematic top plan view of a BAW device. In FIG. 9, the frame region 20B, the active region 20A, and the intermediate region 20C between the active region 20A and the frame region 20B are shown. As illustrated, the active region 20A can correspond to the majority of the area of the BAW device. The frame region 20B at least partially surrounds (e.g., completely surrounds) the active region 20A in the plan view. The cross-sectional view of the BAW devices in this disclosure can be along a line though the BAW device of FIG. 9. FIG. 9 illustrates the BAW device with a pentagon shape with curved sides in plan view. A BAW device in accordance with any suitable principles and advantages disclosed herein can have any other suitable shape in plan view, such as a semi-elliptical shape, a semi-circular shape, a circular shape, an ellipsoid shape, a quadrilateral shape, or a quadrilateral shape with curved sides.

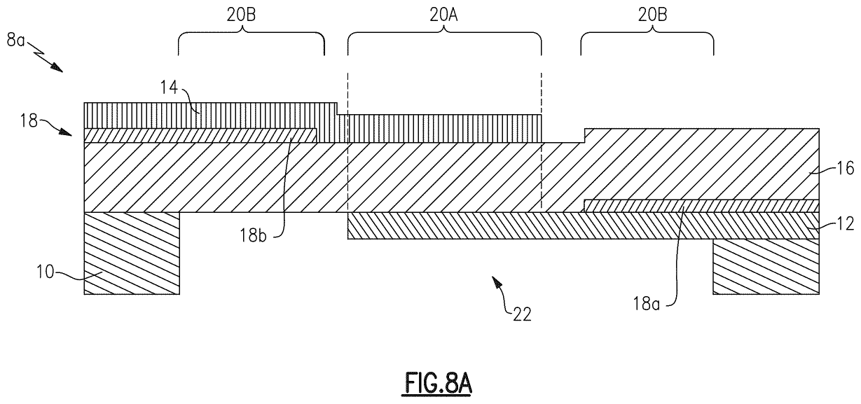

FIG. 10 is an example of a BAW SMR 9 according to an embodiment. Unless otherwise noted, the components of the BAW SMR 9 shown in FIG. 10 may be structurally and/or functionally the same as or generally similar to like components of other BAW devices disclosed herein. The BAW SMR 9 includes a different type of acoustic reflector than other BAW devices disclosed herein. In place of the air cavity 22 shown in one or more other figures, the BAW SMR 9 includes a solid acoustic mirror 45 between the support substrate 10 and the first electrode 12. The acoustic mirror 45 is an example of an acoustic reflector. The illustrated acoustic mirror 45 includes an acoustic Bragg reflector. The illustrated acoustic Bragg reflector can include alternating low impedance layers 46 and high impedance layers 48. As an example, the Bragg reflector can include alternating silicon dioxide layers as low impedance layers 46 and tungsten layers as high impedance layers 48. Any other suitable features of an SMR can alternatively or additionally be implemented. Any other suitable features of BAW devices disclosed herein can be implemented in a BAW SMR.

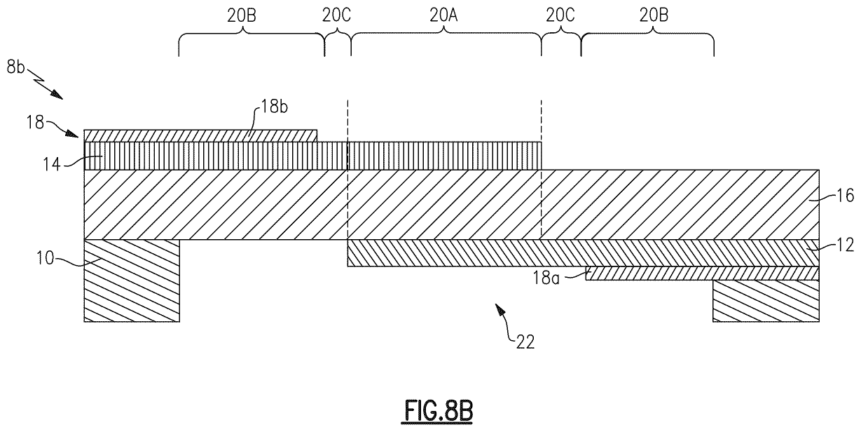

FIG. 11 is a schematic cross-sectional side view of a BAW device 11 according to an embodiment. Unless otherwise noted, the components of the BAW device 11 shown in FIG. 11 may be structurally and/or functionally the same as or generally similar to like components of other BAW devices disclosed herein. The BAW device 11 can be generally similar to the BAW device 4a shown in FIG. 4A, except that the piezoelectric layer 16 in the BAW device 11 is laterally positioned between a layer 50 that has a lower magnitude piezoelectric coefficient than the piezoelectric layer 16. The layer 50 can be a piezoelectric layer that is less piezoelectric than the piezoelectric layer 16. The layer 50 can be a dielectric layer. The layer 50 can be at least partially positioned in the frame region 20B. The layer 50 may further suppress the frame mode in some applications. In certain applications, the layer 50 can provide more mass loading than the piezoelectric layer 16.

BAW devices disclosed herein can be implemented in a variety of applications. Applications of these BAW devices include, but are not limited to, a BAW resonator for filter that filters an electrical signal, a BAW oscillator such as a BAW oscillator for a clock generator, a BAW sensor (e.g., a gas sensor, a particle sensor, a mass sensor, a pressure or touch sensor, etc.), a BAW delay line such as BAW delay line for radar and/or instrumentation applications, an actuator, a microphone, and a speaker. Filters that include BAW resonators can be implemented in a variety of applications including, but not limited to, mobile phones, base stations, repeaters, relays, wireless communication infrastructure, access points, customer premises equipment (CPE), and distributed antenna systems. BAW oscillators can replace crystal oscillators and/or other types of oscillators in a variety of applications, such as but not limited to electronic timing products.

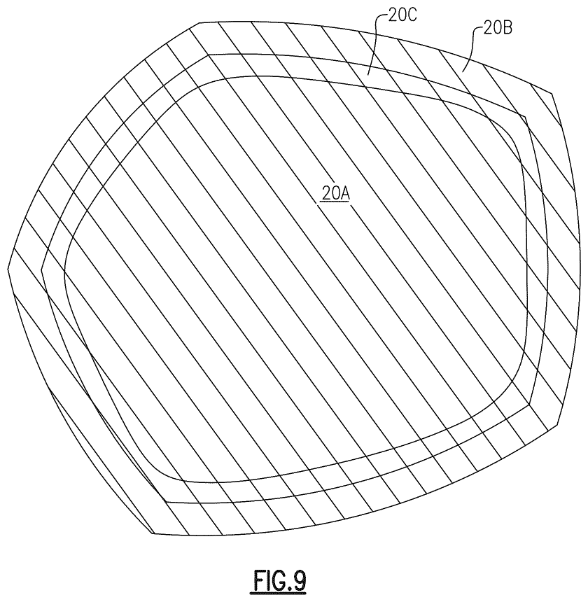

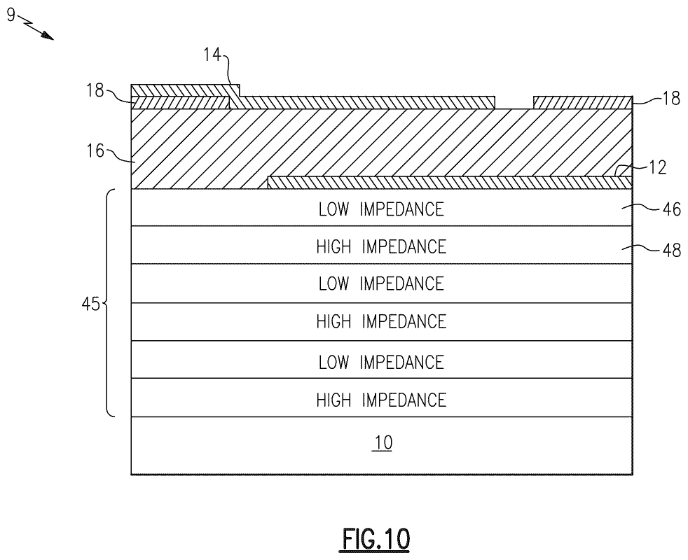

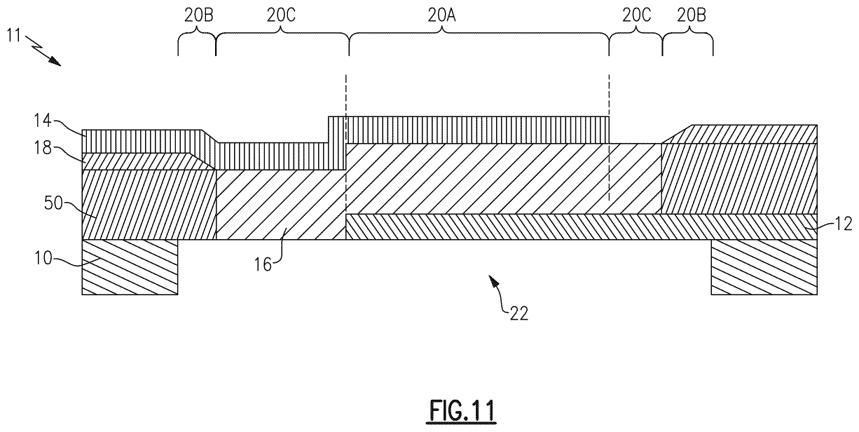

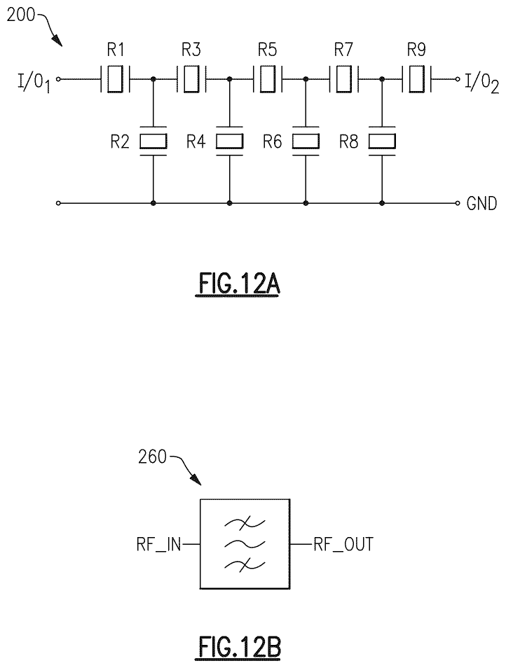

BAW devices disclosed herein can be implemented as BAW resonators in a variety of filters. Such filters can be arranged to filter a radio frequency signal. BAW devices disclosed herein can be implemented in a variety of different filter topologies. Example filter topologies include without limitation, ladder filters, lattice filters, hybrid ladder lattice filters, notch filters where a notch is created by an acoustic wave resonator, hybrid acoustic and non-acoustic inductor-capacitor filters, and the like. The example filter topologies can implement band pass filters. The example filter topologies can implement band stop filters. In some instances, acoustic wave devices disclosed herein can be implemented in filters with one or more other types of resonators and/or with passive impedance elements, such as one or more inductors and/or one or more capacitors. An example filter topology will be discussed with reference to FIG. 12A.

FIG. 12A is a schematic diagram of a ladder filter 200 that includes an acoustic wave resonator according to an embodiment. The ladder filter 200 is an example topology that can implement a band pass filter formed of acoustic wave resonators. In a band pass filter with a ladder filter topology, the shunt resonators can have lower resonant frequencies than the series resonators. The ladder filter 200 can be arranged to filter a radio frequency signal. As illustrated, the ladder filter 200 includes series acoustic wave resonators R1 R3, R5, R7, and R9 and shunt acoustic wave resonators R2, R4, R6, and R8 coupled between a first input/output port I/O₁ and a second input/output port I/O₂. Any suitable number of series acoustic wave resonators can be included in a ladder filter. Any suitable number of shunt acoustic wave resonators can be included in a ladder filter. The first input/output port I/O₁ can be a transmit port and the second input/output port I/O₂ can be an antenna port. Alternatively, the first input/output port I/O₁ can be a receive port and the second input/output port I/O₂ can be an antenna port. One or more of the acoustic wave resonators of the ladder filter 200 can include a BAW resonator in accordance with any suitable principles and advantages disclosed herein. All acoustic resonators of the ladder filter 200 can include a BAW resonator in accordance with any suitable principles and advantages disclosed herein.

A filter that includes a BAW resonator in accordance with any suitable principles and advantages disclosed herein be arranged to filter a radio frequency signal in a fifth generation 5G NR operating band within Frequency Range 1 (FR1). FR1 can be from 410 MHz to 7.125 gigahertz (GHz), for example, as specified in a current 5G NR specification. A filter that includes an acoustic wave resonator in accordance with any suitable principles and advantages disclosed herein can be arranged to filter a radio frequency signal in a fourth generation (4G) Long Term Evolution (LTE) operating band. A filter that includes an acoustic wave resonator in accordance with any suitable principles and advantages disclosed herein can be included in a filter having a passband that includes a 4G LTE operating band and a 5G NR operating band. Such a filter can be implemented in a dual connectivity application, such as an E-UTRAN New Radio-Dual Connectivity (ENDC) application. A multiplexer including any such filters can include one or more other filters with a passband corresponding to a 5G NR operating band and/or a 4G LTE operating band. A filter that includes a BAW resonator in accordance with any suitable principles and advantages disclosed herein be arranged to filter a radio frequency signal in a wireless local area network band (e.g., a Wi-Fi band) or a wireless personal area network band (e.g., a Bluetooth band and/or a ZigBee band).

The BAW resonators disclosed herein can be advantageous for implementing BAW devices with relatively high Qp and relatively low spur intensity. BAW resonators disclosed herein can have significantly better performance than a variety of other BAW resonators. This can be advantageous in meeting demanding specifications for acoustic wave filters, such as performance specifications for certain 5G applications.

FIG. 12B is schematic diagram of an acoustic wave filter 260. The acoustic wave filter 260 can include the acoustic wave resonators of the ladder filter 200. The acoustic wave filter 260 is a band pass filter. The acoustic wave filter 260 is arranged to filter a radio frequency signal. The acoustic wave filter 260 includes one or more acoustic wave devices coupled between a first input/output port RF_IN and a second input/output port RF_OUT. The acoustic wave filter 260 includes a BAW resonator according to an embodiment.

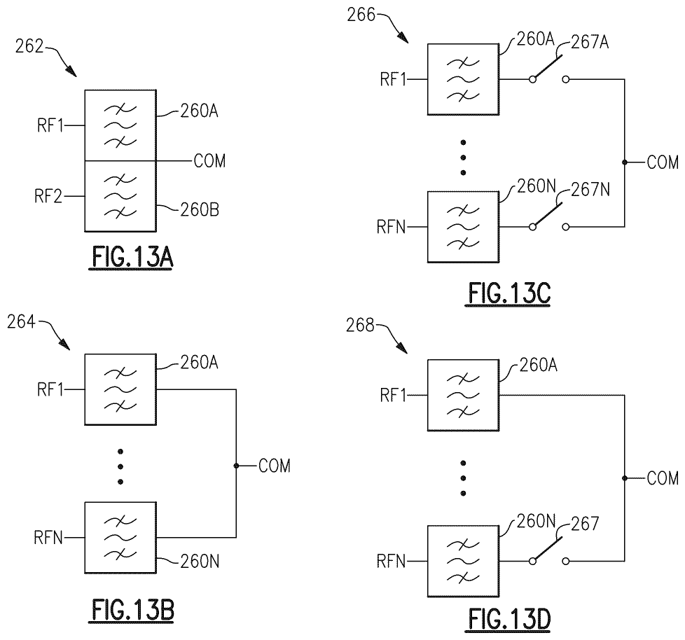

The BAW devices disclosed herein can be implemented in a standalone filter and/or in a filter of any suitable multiplexer. Such filters can be any suitable topology, such as a ladder filter topology. The filter can be a band pass filter arranged to filter a 4G LTE band and/or 5G NR band. Example multiplexers will be discussed with reference to FIGS. 13A to 13D. Any suitable principles and advantages of these multiplexers can be implemented together with each other.

FIG. 13A is a schematic diagram of a duplexer 262 that includes an acoustic wave filter according to an embodiment. The duplexer 262 includes a first filter 260A and a second filter 260B coupled together at a common node COM. One of the filters of the duplexer 262 can be a transmit filter and the other of the filters of the duplexer 262 can be a receive filter. In some other instances, such as in a diversity receive application, the duplexer 262 can include two receive filters. Alternatively, the duplexer 262 can include two transmit filters. The common node COM can be an antenna node.

The first filter 260A is an acoustic wave filter arranged to filter a radio frequency signal. The first filter 260A includes one or more acoustic wave resonators coupled between a first radio frequency node RF1 and the common node COM. The first radio frequency node RF1 can be a transmit node or a receive node. The first filter 260A includes a BAW resonator in accordance with any suitable principles and advantages disclosed herein.

The second filter 260B can be any suitable filter arranged to filter a second radio frequency signal. The second filter 260B can be, for example, an acoustic wave filter, an acoustic wave filter that includes a BAW resonator in accordance with any suitable principles and advantages disclosed herein, an LC filter, a hybrid acoustic wave LC filter, or the like. The second filter 260B is coupled between a second radio frequency node RF2 and the common node. The second radio frequency node RF2 can be a transmit node or a receive node.

Although example embodiments may be discussed with filters or duplexers for illustrative purposes, any suitable principles and advantages disclosed herein can be implement in a multiplexer that includes a plurality of filters coupled together at a common node. Examples of multiplexers include but are not limited to a duplexer with two filters coupled together at a common node, a triplexer with three filters coupled together at a common node, a quadplexer with four filters coupled together at a common node, a hexaplexer with six filters coupled together at a common node, an octoplexer with eight filters coupled together at a common node, or the like. Multiplexers can include filters having different passbands. Multiplexers can include any suitable number of transmit filters and any suitable number of receive filters. For example, a multiplexer can include all receive filters, all transmit filters, or one or more transmit filters and one or more receive filters. One or more filters of a multiplexer can include any suitable number of acoustic wave devices in accordance with any suitable principles and advantages disclosed herein.

FIG. 13B is a schematic diagram of a multiplexer 264 that includes an acoustic wave filter according to an embodiment. The multiplexer 264 includes a plurality of filters 260A to 260N coupled together at a common node COM. The plurality of filters can include any suitable number of filters including, for example, 3 filters, 4 filters, 5 filters, 6 filters, 7 filters, 8 filters, or more filters. Some or all of the plurality of acoustic wave filters can be acoustic wave filters. As illustrated, the filters 260A to 260N each have a fixed electrical connection to the common node COM. This can be referred to as hard multiplexing or fixed multiplexing. Filters have fixed electrical connections to the common node in hard multiplexing applications.

The first filter 260A is an acoustic wave filter arranged to filter a radio frequency signal. The first filter 260A can include one or more acoustic wave devices coupled between a first radio frequency node RF1 and the common node COM. The first radio frequency node RF1 can be a transmit node or a receive node. The first filter 260A includes a BAW resonator in accordance with any suitable principles and advantages disclosed herein. The other filter(s) of the multiplexer 264 can include one or more acoustic wave filters, one or more acoustic wave filters that include a BAW resonator in accordance with any suitable principles and advantages disclosed herein, one or more LC filters, one or more hybrid acoustic wave LC filters, the like, or any suitable combination thereof.

FIG. 13C is a schematic diagram of a multiplexer 266 that includes an acoustic wave filter according to an embodiment. The multiplexer 266 is like the multiplexer 264 of FIG. 13B, except that the multiplexer 266 implements switched multiplexing. In switched multiplexing, a filter is coupled to a common node via a switch. In the multiplexer 266, the switches 267A to 267N can selectively electrically connect respective filters 260A to 260N to the common node COM. For example, the switch 267A can selectively electrically connect the first filter 260A the common node COM via the switch 267A. Any suitable number of the switches 267A to 267N can electrically a respective filter 260A to 260N to the common node COM in a given state. Similarly, any suitable number of the switches 267A to 267N can electrically isolate a respective filter 260A to 260N to the common node COM in a given state. The functionality of the switches 267A to 267N can support various carrier aggregations.

FIG. 13D is a schematic diagram of a multiplexer 268 that includes an acoustic wave filter according to an embodiment. The multiplexer 268 illustrates that a multiplexer can include any suitable combination of hard multiplexed and switched multiplexed filters. One or more acoustic wave devices in accordance with any suitable principles and advantages disclosed herein can be included in a filter (e.g., the filter 260A) that is hard multiplexed to the common node COM of the multiplexer 268. Alternatively or additionally, one or more acoustic wave devices in accordance with any suitable principles and advantages disclosed herein can be included in a filter (e.g., the filter 260N) that is switch multiplexed to the common node COM of the multiplexer 268.

Acoustic wave devices disclosed herein can be implemented in a variety of packaged modules. Some example packaged modules will now be disclosed in which any suitable principles and advantages of the BAW devices disclosed herein can be implemented. The example packaged modules can include a package that encloses the illustrated circuit elements. A module that includes a radio frequency component can be referred to as a radio frequency module. The illustrated circuit elements can be disposed on a common packaging substrate. The packaging substrate can be a laminate substrate, for example. FIGS. 14, 15, and 16 are schematic block diagrams of illustrative packaged modules according to certain embodiments. Any suitable combination of features of these packaged modules can be implemented with each other.

FIG. 14 is a schematic diagram of a radio frequency module 270 that includes an acoustic wave component 272 according to an embodiment. The illustrated radio frequency module 270 includes the acoustic wave component 272 and other circuitry 273. The acoustic wave component 272 can include an acoustic wave filter that includes a plurality of acoustic wave devices, for example. The acoustic wave devices can be BAW devices in certain applications.

The acoustic wave component 272 shown in FIG. 14 includes one or more acoustic wave devices 274 and terminals 275A and 275B. The one or more acoustic wave devices 274 include one or more BAW devices implemented in accordance with any suitable principles and advantages disclosed herein. The terminals 275A and 274B can serve, for example, as an input contact and an output contact. Although two terminals are illustrated, any suitable number of terminals can be implemented for a particular application. The acoustic wave component 272 and the other circuitry 273 are on a common packaging substrate 276 in FIG. 14. The packaging substrate 276 can be a laminate substrate. The terminals 275A and 275B can be electrically connected to contacts 277A and 277B, respectively, on the packaging substrate 276 by way of electrical connectors 278A and 278B, respectively. The electrical connectors 278A and 278B can be bumps or wire bonds, for example.

The other circuitry 273 can include any suitable additional circuitry. For example, the other circuitry can include one or more radio frequency amplifiers (e.g., one or more power amplifiers and/or one or more low noise amplifiers), one or more radio frequency switches, one or more additional filters, one or more RF couplers, one or more delay lines, one or more phase shifters, the like, or any suitable combination thereof. Accordingly, the other circuitry 273 can include one or more radio frequency circuit elements. The other circuitry 273 can be electrically connected to the one or more acoustic wave devices 274. The radio frequency module 270 can include one or more packaging structures to, for example, provide protection and/or facilitate easier handling of the radio frequency module 270. Such a packaging structure can include an overmold structure formed over the packaging substrate 276. The overmold structure can encapsulate some or all of the components of the radio frequency module 270.

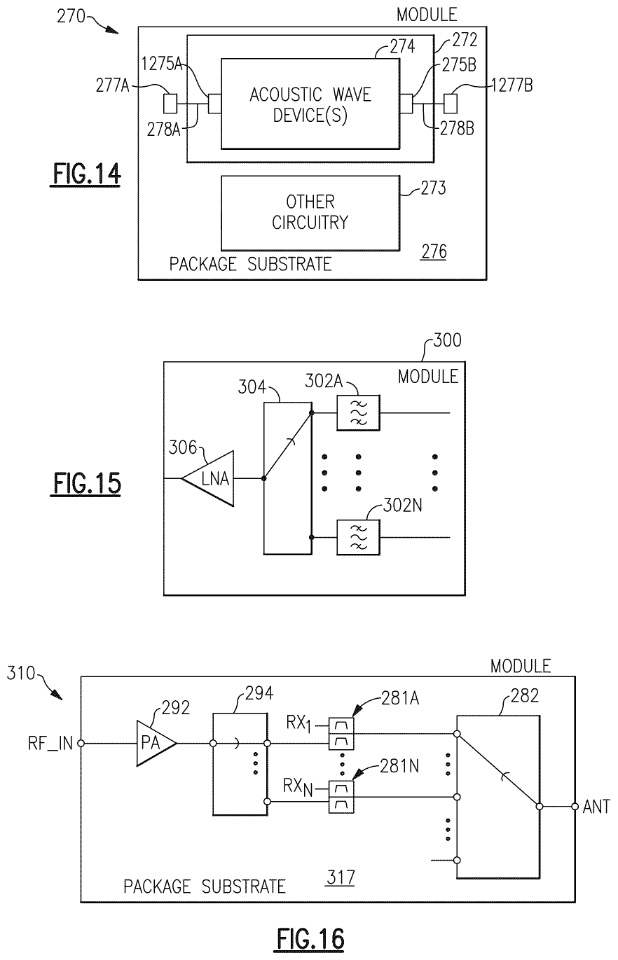

FIG. 15 is a schematic block diagram of a module 300 that includes filters 302A to 302N, a radio frequency switch 304, and a low noise amplifier 306 according to an embodiment. One or more filters of the filters 302A to 302N can include any suitable number of bulk acoustic wave devices in accordance with any suitable principles and advantages disclosed herein. Any suitable number of filters 302A to 302N can be implemented. The illustrated filters 302A to 302N are receive filters. One or more of the filters 302A to 302N can be included in a multiplexer that also includes a transmit filter and/or another receive filter. The radio frequency switch 304 can be a multi-throw radio frequency switch. The radio frequency switch 304 can electrically couple an output of a selected filter of filters 302A to 302N to the low noise amplifier 306. In some embodiments, a plurality of low noise amplifiers can be implemented. The module 300 can include diversity receive features in certain applications.

FIG. 16 is a schematic diagram of a radio frequency module 310 that includes an acoustic wave filter according to an embodiment. As illustrated, the radio frequency module 310 includes duplexers 316A to 316N, a power amplifier 312, a radio frequency switch 314 configured as a select switch, and an antenna switch 318. The radio frequency module 310 can include a package that encloses the illustrated elements. The illustrated elements can be disposed on a common packaging substrate 317. The packaging substrate 317 can be a laminate substrate, for example. A radio frequency module that includes a power amplifier can be referred to as a power amplifier module. A radio frequency module can include a subset of the elements illustrated in FIG. 16 and/or additional elements. The radio frequency module 310 may include any one of the acoustic wave filters that include at least one bulk acoustic wave resonator in accordance with any suitable principles and advantages disclosed herein.

The duplexers 316A to 316N can each include two acoustic wave filters coupled to a common node. For example, the two acoustic wave filters can be a transmit filter and a receive filter. As illustrated, the transmit filter and the receive filter can each be a band pass filter arranged to filter a radio frequency signal. One or more of the transmit filters can include a BAW device in accordance with any suitable principles and advantages disclosed herein. Similarly, one or more of the receive filters can include a BAW device in accordance with any suitable principles and advantages disclosed herein. Although FIG. 16 illustrates duplexers, any suitable principles and advantages disclosed herein can be implemented in other multiplexers (e.g., quadplexers, hexaplexers, octoplexers, etc.) and/or in switched multiplexers and/or with standalone filters.

The power amplifier 312 can amplify a radio frequency signal. The illustrated radio frequency switch 314 is a multi-throw radio frequency switch. The radio frequency switch 314 can electrically couple an output of the power amplifier 312 to a selected transmit filter of the transmit filters of the duplexers 316A to 316N. In some instances, the radio frequency switch 314 can electrically connect the output of the power amplifier 312 to more than one of the transmit filters. The antenna switch 318 can selectively couple a signal from one or more of the duplexers 316A to 316N to an antenna port ANT. The duplexers 316A to 316N can be associated with different frequency bands and/or different modes of operation (e.g., different power modes, different signaling modes, etc.).

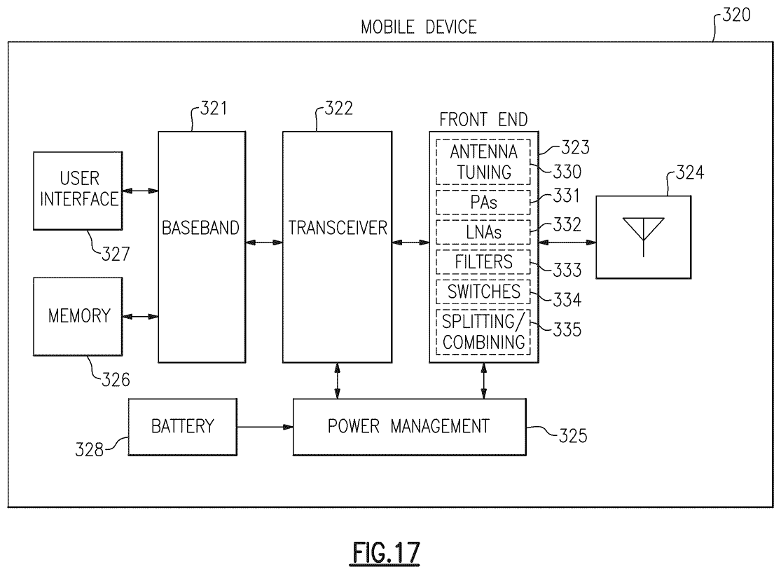

The BAW devices disclosed herein can be implemented in wireless communication devices. FIG. 17 is a schematic block diagram of a wireless communication device 320 that includes a BAW device according to an embodiment. The wireless communication device 320 can be a mobile device. The wireless communication device 320 can be any suitable wireless communication device. For instance, a wireless communication device 320 can be a mobile phone, such as a smart phone. As illustrated, the wireless communication device 320 includes a baseband system 321, a transceiver 322, a front end system 323, one or more antennas 324, a power management system 325, a memory 326, a user interface 327, and a battery 328.

The wireless communication device 320 can be used communicate using a wide variety of communications technologies, including, but not limited to, 2G, 3G, 4G (including LTE, LTE-Advanced, and/or LTE-Advanced Pro), 5G NR, WLAN (for instance, Wi-Fi), WPAN (for instance, Bluetooth and/or ZigBee), WMAN (for instance, WiMax), and/or GPS technologies.

The transceiver 322 generates RF signals for transmission and processes incoming RF signals received from the antennas 324. Various functionalities associated with the transmission and receiving of RF signals can be achieved by one or more components that are collectively represented in FIG. 17 as the transceiver 322. In one example, separate components (for instance, separate circuits or dies) can be provided for handling certain types of RF signals.

The front end system 323 aids in conditioning signals provided to and/or received from the antennas 324. In the illustrated embodiment, the front end system 323 includes antenna tuning circuitry 330, power amplifiers (PAS) 331, low noise amplifiers (LNAs) 332, filters 333, switches 334, and signal splitting/combining circuitry 335. However, other implementations are possible. The filters 333 can include one or more acoustic wave filters that include any suitable number of BAW devices in accordance with any suitable principles and advantages disclosed herein.

For example, the front end system 323 can provide a number of functionalities, including, but not limited to, amplifying signals for transmission, amplifying received signals, filtering signals, switching between different bands, switching between different power modes, switching between transmission and receiving modes, duplexing of signals, multiplexing of signals, or any suitable combination thereof.

In certain implementations, the wireless communication device 320 supports carrier aggregation, thereby providing flexibility to increase peak data rates. Carrier aggregation can be used for Frequency Division Duplexing (FDD) and/or Time Division Duplexing (TDD), and may be used to aggregate a plurality of carriers and/or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 324 can include antennas used for a wide variety of types of communications. For example, the antennas 324 can include antennas for transmitting and/or receiving signals associated with a wide variety of frequencies and communications standards.

In certain implementations, the antennas 324 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The wireless communication device 320 can operate with beamforming in certain implementations. For example, the front end system 323 can include amplifiers having controllable gain and phase shifters having controllable phase to provide beam formation and directivity for transmission and/or reception of signals using the antennas 324. For example, in the context of signal transmission, the amplitude and phases of the transmit signals provided to the antennas 324 are controlled such that radiated signals from the antennas 324 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 324 from a particular direction. In certain implementations, the antennas 324 include one or more arrays of antenna elements to enhance beamforming.

The baseband system 321 is coupled to the user interface 327 to facilitate processing of various user input and output (I/O), such as voice and data. The baseband system 321 provides the transceiver 322 with digital representations of transmit signals, which the transceiver 322 processes to generate RF signals for transmission. The baseband system 321 also processes digital representations of received signals provided by the transceiver 322. As shown in FIG. 17, the baseband system 321 is coupled to the memory 326 of facilitate operation of the wireless communication device 320.

The memory 326 can be used for a wide variety of purposes, such as storing data and/or instructions to facilitate the operation of the wireless communication device 220 and/or to provide storage of user information.

The power management system 325 provides a number of power management functions of the wireless communication device 320. In certain implementations, the power management system 325 includes a PA supply control circuit that controls the supply voltages of the power amplifiers 331. For example, the power management system 325 can be configured to change the supply voltage(s) provided to one or more of the power amplifiers 331 to improve efficiency, such as power added efficiency (PAE).

As shown in FIG. 17, the power management system 325 receives a battery voltage from the battery 328. The battery 328 can be any suitable battery for use in the wireless communication device 320, including, for example, a lithium-ion battery.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes example embodiments, the teachings described herein can be applied to a variety of structures. Any of the principles and advantages discussed herein can be implemented in association with RF circuits configured to process signals having a frequency in a range from about 30 kHz to 300 GHz, such as in a frequency range from about 400 MHz to 8.5 GHZ, in FR1, in a frequency range from about 2 GHz to 10 GHz, in a frequency range from about 2 GHz to 15 GHz, or in a frequency range from 5 GHz to 20 GHz.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a robot such as an industrial robot, an Internet of things device, a stereo system, a digital music player, a radio, a camera such as a digital camera, a portable memory chip, a home appliance such as a washer or a dryer, a peripheral device, a wrist watch, a clock, etc. Further, the electronic devices can include unfinished products.

Unless the context indicates otherwise, throughout the description and the claims, the words “comprise,” “comprising,” “include,” “including” and the like are to generally be construed in an inclusive sense, as opposed to an exclusive or exhaustive sense; that is to say, in the sense of “including, but not limited to.” Conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively.

While certain embodiments have been described, these embodiments have been presented by way of example only, and are not intended to limit the scope of the disclosure. Indeed, the novel resonators, filters, multiplexer, devices, modules, wireless communication devices, apparatus, methods, and systems described herein may be embodied in a variety of other forms. Furthermore, various omissions, substitutions, and changes in the form of the resonators, filters, multiplexer, devices, modules, wireless communication devices, apparatus, methods, and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and/or acts of the various embodiments described above can be combined to provide further embodiments. The accompanying claims and their equivalents are intended to cover such forms or modifications as would fall within the scope and spirit of the disclosure.

What is claimed is:

1. A bulk acoustic wave device having an active region and a frame region outside of the active region, the bulk acoustic wave device comprising:
an acoustic reflector;
electrodes including a first electrode and a second electrode;
a piezoelectric layer, the first electrode and the second electrode being on opposing sides of the piezoelectric layer over the acoustic reflector in the active region; and
a frame structure positioned over the acoustic reflector in the frame region and outside of the active region.

2. The bulk acoustic wave device of claim 1 wherein the frame structure includes a raised frame structure.

3. The bulk acoustic wave device of claim 1 wherein the frame structure includes a multi-layer raised frame structure.

4. The bulk acoustic wave device of claim 1 wherein the frame structure includes a recessed frame structure.

5. The bulk acoustic wave device of claim 1 wherein the frame structure is a floating raised frame structure.

6. The bulk acoustic wave device of claim 1 wherein the frame structure is positioned between the piezoelectric layer and one of the electrodes.

7. The bulk acoustic wave device of claim 1 wherein the first electrode is positioned between the frame structure and the piezoelectric layer.

8. The bulk acoustic wave device of claim 1 wherein the frame region laterally surrounds the active region.

9. The bulk acoustic wave device of claim 1 wherein the frame region is spaced apart from the active region by an intermediate region.

10. The bulk acoustic wave device of claim 1 wherein the acoustic reflector is an air cavity.

11. The bulk acoustic wave device of claim 1 wherein the frame structure is symmetric about an axis extending through the piezoelectric layer.

12. The bulk acoustic wave device of claim 11 wherein the frame structure includes a first raised frame layer and a second raised frame layer, the first raised frame layer is on an opposite side of the piezoelectric layer than the second raised frame layer.

13. The bulk acoustic wave device of claim 1 wherein a surface of the piezoelectric layer is flat at least in the active region.

14. The bulk acoustic wave device of claim 13 wherein the surface of the piezoelectric layer is flat in an intermediate region between the active region and the frame region.

15. The bulk acoustic wave device of claim 1 wherein the frame structure includes a gap between the second electrode and the piezoelectric layer that creates a suspended frame structure.

16. The bulk acoustic wave device of claim 1 wherein the first electrode is shorted to metal on an opposing side of the piezoelectric layer.

17. A bulk acoustic wave device comprising:
an acoustic reflector;
electrodes including a first electrode and a second electrode;
a piezoelectric layer positioned vertically between the first and second electrodes over the acoustic reflector in an active region, the first and second electrodes overlapping in the active region; and
a frame structure over the acoustic reflector in a frame region and outside the active region, the frame region being laterally offset from the active region.

18. The bulk acoustic wave device of claim 17 wherein the frame region laterally surrounds the active region.

19. The bulk acoustic wave device of claim 17 wherein the acoustic reflector is an air gap.

20. A radio frequency module comprising:
a filter including a bulk acoustic wave device, the bulk acoustic wave device including an acoustic reflector; electrodes including a first electrode and a second electrode; a piezoelectric layer, the first electrode and the second electrode being on opposing sides of the piezoelectric layer over the acoustic reflector in an active region of the bulk acoustic wave device; and a frame structure positioned over the acoustic reflector in a frame region of the bulk acoustic wave device and outside the active region of the bulk acoustic wave device;
radio frequency circuitry; and
a package structure enclosing the filter and the radio frequency circuitry.
